(19) United States
(12) Patent Application Publication
(10) Pub. No.: US 2016/0332792 A1
(43) Pub. Date: Nov. 17, 2016

(54) Metallized Water-Marked Films and Methods of Manufacture and Use Thereof

(71) Applicant: Printpack Illinois, Inc., Elgin, IL (US)

(72) Inventors: William J. Barlow, JR., Marietta, GA (US); Jeffrey Allen Boekeloo, Acworth, GA (US); Rajesh Suryanarayanan, Powder Springs, GA (US)

(21) Appl. No.: 15/153,056

(22) Filed: May 12, 2016

Related U.S. Application Data
(60) Provisional application No. 62/161,066, filed on May 13, 2015.

(51) Int. Cl. B65D 65/42; B41F 5/24; B05D 7/00; B05D 7/04; B65D 75/04; C23C 14/20

(52) U.S. Cl. CPC B65D 65/42; B65D 75/04; C23C 14/20; B05D 7/54; B05D 7/04; B41F 5/24

(57) ABSTRACT

Metallized water-marked films and methods of manufacture thereof are provided. The metallized water-marked films include at least a base substrate, a coating layer in the form of one or more markings that are each substantially free of pigment on at least a first portion of a first surface of the base substrate, and a metallized layer disposed over the coating layer and at least a portion of a second portion of the first surface of the base substrate. Packages for containing a product therein, methods for making the packages, and methods for packaging a product that employ the metallized water-marked films are also provided. Also provided are rolls of film for forming a package that include the metallized water-marked films.

### CROSS-REFERENCE TO RELATED APPLICATIONS

This application claims priority to U.S. Provisional Application No. 62/161,066, filed May 13, 2015, which is incorporated herein by reference in its entirety.

### FIELD OF THE INVENTION

This present disclosure is generally in the field of packaging material, and more particularly to films and packages made therefrom, which, for example, may include metallized water-marked films.

### BACKGROUND

Webs of films are manufactured for many purposes, e.g., as packaging material wherein each web of film is printed with inks to form watermarks (e.g., logos, graphics, or messages) thereon, and later formed into a package. The printed films may also be metallized for enhancing graphic appeal. Typically, physical vapor deposition (PVD) methods are used in the metallization of printed films. The base substrates, designed for metallizing, have an engineered surface to enable effective metal deposition thereon. Metallizing substrates, formulated via polymer chemistry, additive chemistry, and surface treatment chemistry, provide a smooth surface for metal to adhere thereto.

Most, if not all, inks that are printed onto the film contain a high level of pigment, which presents issues when the printed film is metallized. For example, the high level of pigment creates rough surface areas, which is otherwise smooth, thereby causing a discontinuous metallized layer. This discontinuous metallized layer negatively impacts the moisture and oxygen barrier properties of the printed film.

Accordingly, there exists a need to provide improved printed films with visual watermarks that are capable of being metallized with minimal impact on the moisture and oxygen barrier properties and performance of the resulting metallized film.

### SUMMARY

In one aspect, metallized water-marked films are provided. In one embodiment, the metallized water-marked film includes a base substrate having a first surface and a second surface opposite the first surface, a coating layer on at least a first portion of the first surface of the base substrate, wherein the coating layer is in the form of one or more markings that are each substantially free of pigment and the first surface of the base portion further includes a second portion uncoated with the coating layer, and a metallized layer disposed over the coating layer and at least a portion of the second portion, wherein the coating layer is located between the base substrate and the metallized layer.

In another aspect, methods for fabricating the metallized water-marked film are provided. In one embodiment, the method includes applying a coating layer on at least a first portion of a first surface of a base substrate, wherein the coating layer is in the form of one or more markings that are each substantially free of pigment and the first surface of the base portion further includes a second portion uncoated with the coating layer, and disposing a metallized layer over the coating layer and at least a portion of the second portion, wherein the coating layer is located between the base substrate and the metallized layer.

In yet another aspect, packages for containing a product therein are provided. In one embodiment, the package is a flexible container formed from the metallized water-marked film, as described above, in which the flexible container has a front side and a back side sealed together along at least one longitudinal seam and two lateral end seams.

In another aspect, methods for fabricating a package for containing a product therein are provided. In one embodiment the method includes forming the metallized water-marked film, as described above, into a flexible container having a front side and a back side sealed together along at least one longitudinal seam and two lateral end seams.

In yet another aspect, methods for packaging a product are provided. In one embodiment, the method includes providing a metallized water-marked film, as described above, folding the metallized water-marked film into a tubular form, forming a longitudinal sealed seam by joining opposite longitudinal edges of the tubularly formed metallized water-marked film, forming a first traverse end sealed seam, introducing a product into the tubularly formed metallized water-marked film, and forming a second traverse end sealed seam to enclose the product therein.

In another aspect, rolls of flexible film for forming a package for containing a product therein are provided. In one embodiment, the roll of flexible film includes the metallized water-marked film, as described above.

### BRIEF DESCRIPTION OF THE DRAWINGS

FIG. 1A is top view of a metallized water-marked film in accordance with an embodiment of the present disclosure.

FIG. 1B is a cross-sectional view of the metallized water-marked film in FIG. 1A taken at 1-1.

FIG. 2A is top view of a metallized water-marked film in accordance with an embodiment of the present disclosure.

FIG. 2B is a cross-sectional view of the metallized water-marked film in FIG. 2A taken at 2-2.

FIG. 3A is a front view of a package formed from the metallized water-marked film shown in FIGS. 1A and 1B in accordance with an embodiment of the present disclosure.

FIG. 3B is a back view of the package shown in FIG. 3A.

FIG. 4 is a graph comparing the moisture transmission rate of metallized films printed with four different ink systems at various pigment loadings.

FIG. 5 is a graph illustrating the oxygen transmission rate of metallized films printed with four different ink systems at various pigment loadings.

### DETAILED DESCRIPTION

Improved metallized water-marked films have been developed that address the challenges that arise when metallizing a film having visual watermarks printed thereon. These metallized water-mark films are printed with watermarks comprising inks substantially free of pigment, thereby advantageously minimizing the effect on barrier properties of the film. That is, the metallized water-mark films as described herein have higher barrier properties compared to conventional metallized water-marked films, i.e., water-marked films that include high pigment loaded watermarks.

Several embodiments of the metallized water-marked films, packages made therefrom, methods for making these water-marked films and packages, and methods for packaging products within the packages are described herein. Parameters of different steps, components, and features of the embodiments are described separately, but may be combined consistently with this description of claims, to enable other embodiments as well to be understood by those skilled in the art. Various terms used herein are likewise defined in the description which follows.

Values or ranges may be expressed herein as “about”, from “about” one particular value, and/or to “about” another particular value. When such values or ranges are expressed, other embodiments disclosed include the specific value recited, from the one particular value, and/or to the other particular value. Similarly, when values are expressed as approximations, by use of the antecedent “about,” it will be understood that the particular value forms another embodiment. It will be further understood that there are a number of values disclosed therein, and that each value is also herein disclosed as “about” that particular value in addition to the value itself.

Metallized water-marked films have been developed that generally include a base substrate, a coating layer, and a metallized layer, in which the coating layer, located between the base substrate and metallized layer, is in the form of one or more markings that are each substantially free of pigment. The compositional make-up of the coating layer and the layer sequences of the metallized water-marked films described herein beneficially enable these films to have high barrier properties. That is, the metallized water-marked films disclosed herein advantageously display an improved metallizing processing capability, thereby providing the ability to produce a metallized water-marked film having watermarks without significantly affecting the barrier properties of the film and the packages made therefrom. As such, the metallized water-marked films beneficially provide the ability to extend the shelf life of packaged products, as well as producing films for packages that would otherwise not incorporate watermarks, e.g. “bag-in-the box” packaging, due to the risk of compromising barrier properties of the film.

The metallized water-marked films described herein can be employed in the industrial market for radiant barrier/reflective insulation products, electronics packaging, cosmetic packaging, and a host of industrial solutions for vend-sized distribution bags of coffee, salty snacks, confectionery goods, and the like. Additionally, the metallized water-marked films can be incorporated into packaging as a security feature.

As used herein, the phrase “substantially free of pigment” refers to pigment present in the amount from about 0.0% (v/v) to about 5.0% (v/v) based on the volume of each marking.

Water-Marked Films and Methods of Manufacture

In accordance with the description, metallized water-marked films that exhibit improved metallizing processing capabilities, resulting in improved barrier properties compared to conventional metallized water-marked films, have been developed for the manufacture of packages.

In one embodiment, the metallized water-marked film includes a base substrate having a first surface, with first and second portions, and a second surface opposite the first surface, a coating layer, in the form of one or more markings that are substantially free of pigment, on at least the first portion of the first surface of the base substrate, and a metallized layer disposed over the coating layer and at least a portion of the second portion, wherein the coating layer is located between the base substrate and the metallized layer.

The metallized water-marked films described herein have a moisture vapor transmission rate (MVTR) that minimizes the transfer of moisture through the metallized water-marked film, and therefore through the packages made therefrom, either to the outside environment or to a product contained therein. The MVTR is the steady state rate at which water vapor permeates through a film at specified conditions of temperature and relative humidity, and can be determined using ASTM E96E. In embodiments, the metallized water-marked films have a MVTR that does not substantially affect the barrier properties thereof, thereby rendering these films unsuitable for use in applications, such as packaging.

The metallized water-marked films described herein have an oxygen transmission rate (OTR) that minimizes the transfer of oxygen gas through the metallized water-marked film, and therefore through the packages made therefrom, either to the outside environment or to a product contained therein. The OTR is the steady state rate at which oxygen gas permeates through a film at specified conditions of temperature and zero relative humidity, and can be determined using ASTM D3985. In embodiments, the metallized water-marked films have an OTR that does not substantially affect the barrier properties thereof, thereby rendering these films unsuitable for use in applications, such as packaging.

As used herein, the phrase “without significantly” when used with respect to the effect on the barrier properties of the film means a lack of change in MVTR and OTR that results in rendering films with unsuitable barrier properties for applications, such as packaging.

In embodiments, the first surface of the base substrate includes first and second portions, in which the first portion is coated with the coating layer as described below. The base substrate may be formed from a single or multi-layer film using one or more flexible film materials suitable for use in packaging. For example, in certain embodiments, the flexible film materials may include one or more layers of one or more polymeric materials. Non-limiting examples of suitable polymeric materials include polyolefins, polyesters, polyamides, and the like, and combinations thereof, it being understood that many other polymers and copolymers are also suitable. These materials may be produced as a cast or blown film and may be subsequently bi-axially or mono-axially oriented.

In embodiments, the metallized water-marked films also include a coating layer on at least the first portion of the first surface of the base substrate. The coating layer is in the form of one or more markings that are each substantially free of pigment. In some embodiments, the one or more markings are in the form of one or more words, one or more numbers, one or more letters, one or more shapes, one or more symbols, one or more patterns, or combinations thereof.

In some embodiments, the coating layer comprises an ink system. Non-limiting examples of suitable ink systems include a nitro-cellulose-based ink system, a polyurethane-based ink system, a polyester-based ink system, a polyamide-based ink system. In one embodiment, the coating layer comprises a combination of two or more ink systems.

In embodiments where the one or more markings comprise pigment, the pigment particulates have a particle size that does not provide the coating layer with a surface roughness that substantially impedes the barrier properties of the resulting metallized water-marked film.

Without being bound to one single theory, the first surface of the coating layer has a surface smoothness such that the coating layer provides a suitable, secondary metallizable surface, in addition to the second portion of the base substrate, thereby minimizing the adverse effects on the barrier properties of the metallized water-marked film. Surface roughness indicates the degree of irregularity or unevenness of a plan surface. In metallizing processes, the surface or surfaces on which metal is to be disposed are generally smooth (minimally, if at all, rough). The lack of surface roughness enables effective metal deposition. It has been found that the more rough the surface, the less effective the metal to surface adhesion, leading to ineffective metal deposition. A discontinuous metallized layer negatively affects the barrier properties of the overall metallized film.

In embodiments, the coating layer has a surface roughness that enables effective metal deposition thereon, and therefore does not substantially impede the barrier properties of the resulting metallized water-marked film.

Without being bound to one single theory, the refractive index of the coating layer enables visibility of the coating layer through the metallized layer of the metallized water-marked films described herein, even though the one or more markings of the coating layer are substantially free of pigment. That is, although the presence of pigment enhances the visibility of the coating layer, it is the reflective nature of the coating layer that largely facilitates visibility. As such, the visibility of the coating layer of the metallized water-marked films is primarily a function of the reflective properties of the coating layer itself, rather the amount, if any, pigment.

In embodiments, each of the one or more markings has a refractive index that provides the coating layer with the ability to effectively reflect light such that the coating layer is visible. In a certain embodiment, each of the one or more markings has substantially the same refractive index. In another embodiment, each of the one or more markings has different refractive indexes. In yet another embodiment, where the coating layer comprises more than one marking, a first set of the markings has a first refractive index and a second set of markings has a second refractive index.

In embodiments, the metallized water-marked film also includes a metallized layer that is disposed over the coating layer and at least a portion of the second portion of the base substrate. As such, the coating layer is located between the base substrate and the metallized layer. Non-limiting examples of suitable metals within the metallized layer include aluminum, and the like, it being understood that many other metals are also suitable.

In embodiments, the metallized water-marked film has a refractive index that enables effective visibility of the coating layer.

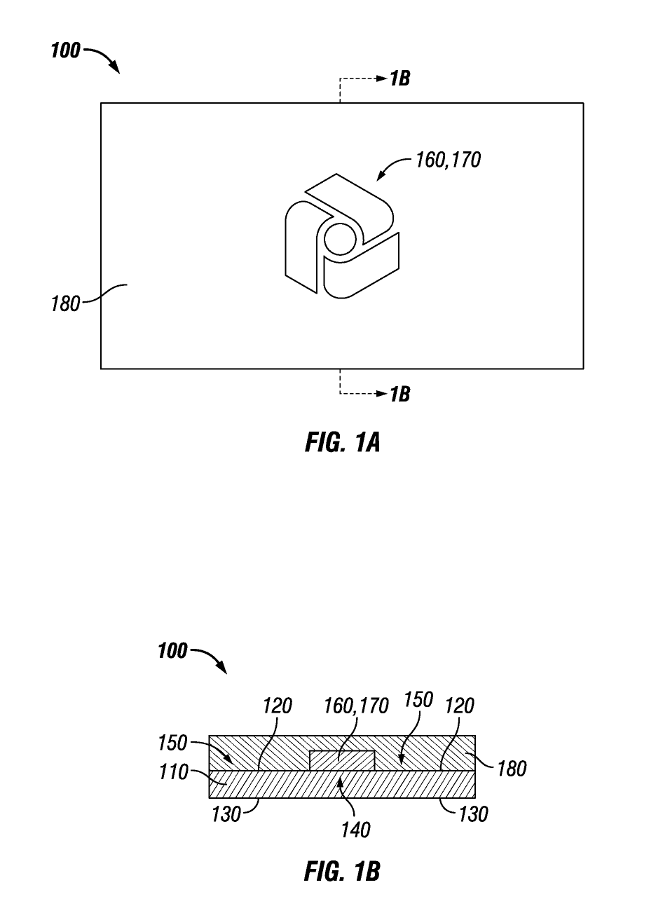

FIGS. 1A and 1B illustrate an exemplary metallized water-marked film 100. The metallized water-marked film 100 includes a base substrate 110, a coating layer 160, and a metallized layer 180, in which the coating layer 160 is located between the base substrate 110 and the metallized layer 180. The base substrate 110 has a first surface 120 and a second surface 130 opposite the first surface 120. The first surface 120 includes a first portion 140 and a second portion 150. The coating layer 160, in the form of one or more markings 170, is on the first portion 140 of the first surface 120 of the base substrate 110. The metallized layer 180 is disposed on the coating layer 160 and the second portion 150 of the base substrate 110, thereby embedding or burying the coating layer 160 between the base substrate 110 and the metallizing layer 180.

In some embodiments, the metallized water-marked films also include an overcoat layer over at least the first portion and located between the metallized layer and at least the coating layer. Non-limiting examples of suitable overcoat layers include clear, non-particulate containing coatings, over print varnishes (OPVs), lacquers, primers, and the like. In one embodiment, the overcoat layer comprises acrylics, acrylates, styrene, polyolefins, polyamides, polyesters, polyurethanes, polyvinyl alcohols, or combinations thereof.

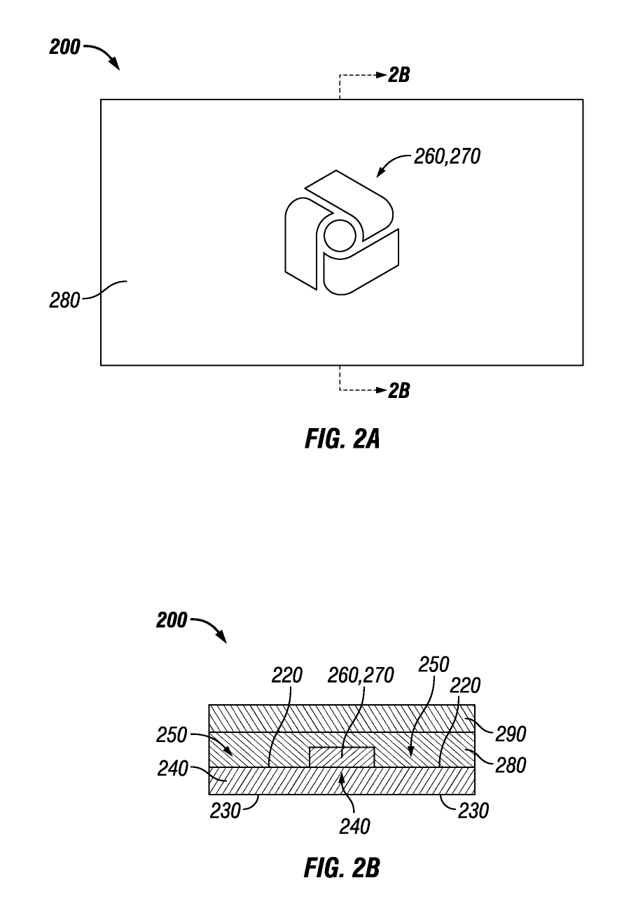

FIGS. 2A and 2B illustrate an exemplary metallized water-marked film 200. The metallized water-marked film 200 includes a base substrate 210, a coating layer 260, a metallized layer 280, and an overcoat layer 290. The coating layer 260 is located between the base substrate 210 and the metallized layer 280 and the overcoat layer 290 is located between the metallized layer 280 and the coating layer 260. The base substrate 210 has a first surface 220 and a second surface 230 opposite the first surface 220. The first surface 220 includes a first portion 240 and a second portion 250. The coating layer 260, in the form of one or more markings 270, is on the first portion 240 of the first surface 220 of the base substrate 210. The overcoat layer 290 is over the first portion 240, atop the coating layer 260. The metallized layer 280 is disposed on the overcoat layer 290 and the second portion 250 of the base substrate 210, thereby embedding or burying the coating layer 260 between the base substrate 210 and the overcoat layer 290.

The metallized water-marked films described herein may be formed by way of printing and in some embodiments, additional extrusion (e.g., melt extrusion), lamination, or the like, or combinations thereof, followed by metallizing. Once formed, the metallized water-marked film is either directly fed or first stored as a roll and later fed into a packaging process, such as Form-Fill-Seal (FFS).

In one embodiment, a method for fabricating a metallized water-marked film includes applying a coating layer on at least a first portion of a first surface of a base substrate, wherein the coating layer is in the form of one or more markings that are each substantially free of pigment and the first surface of the base portion further includes a second portion uncoated with the coating layer, and disposing a metallized layer over the coating layer and at least a portion of the second portion, wherein the coating layer is located between the base substrate and the metallized layer. In such embodiments, the metallized water-marked film has a moisture transmission rate and an oxygen transmission rate that does not impede the overall barrier properties such that the film and the packages made therefrom are rendered unsuitable.

In some embodiments, the step of applying the coating layer comprises flexographic printing, gravure printing, or a combination of flexographic printing and gravure printing the coating layer on at least the first portion of the first surface of the base substrate.

In some embodiments, the step of disposing the metallized layer comprises vacuum depositing the metallized layer over the coating layer and at least a portion of the second portion.

In certain embodiments, the method further includes applying an overcoat layer over at least the first portion, wherein the metallized layer is disposed on a first surface of the overcoat layer and at least a portion of the second portion of the base substrate such that the overcoat layer is located between the metallized layer and at least the coating layer.

Packages and Methods of Manufacture

The metallized water-marked film described herein may be used to form a package for containing a product therein. In certain embodiments, a roll of flexible film comprising a metallized water-marked film described herein may be used to form a package.

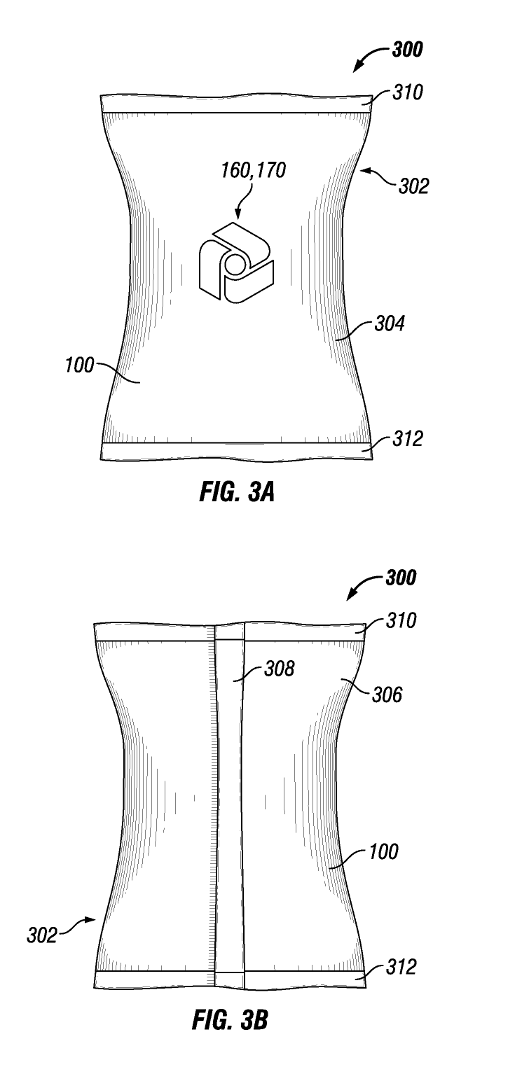

As shown in FIGS. 3A and 3B, in one embodiment, a package 300, includes a flexible container 302 formed from the metallized water-marked film 100 of FIGS. 1A and 1B, in which the flexible container 302 has a front side 304 and a back side 306. The front side 304 and the back side 306 are sealed together along at least one longitudinal seam 308 and two lateral end seams 310, 312.

The packages as described herein may be formed from the metallized water-marked film, for example, by a horizontal or vertical FFS process using heat sealing, cold sealing, ultrasonic sealing, radio frequency welding, induction welding or combinations thereof to form the at least one longitudinal seam and the two lateral end seams. In some embodiments, the metallized water-marked film may be constructed of layers of up to about 700 gauge thickness.

The packages are formed from metallized water-marked films described herein that have been developed to enable the incorporation of a visible coating layer in the form of one or more markings with minimal, if any, adverse effects on the barrier properties of the package. In one embodiment, the method for fabricating a package for containing a product therein may include forming a metallized water-marked film into a flexible container having a front side and a back side sealed together along at least one longitudinal seam and two lateral end seams. For example, the metallized water-marked film may be fed from a roll and then folded to the desired package shape and stabilized by heat sealing the longitudinal seam and the first of the two lateral end seams. The product may then be placed into the formed package, and the remaining opening, i.e. the second of the two lateral end seams, is sealed. Machines can be configured so that the metallized water-marked film travels horizontally through the machine (horizontal FFS) or vertically through the machine (vertical FFS) for food and non-food production.

Accordingly in some embodiments, the packages described herein may be used for containing a variety of products, for example pourable dry-food products, particularly food products. Non-limiting examples of such products include cereal, chips, crackers, cookies, baked goods, snack foods, and the like. In other embodiments, the package herein may be used for containing consumer products, for example electronics, cosmetics, etc. The metallized water-marked films described herein enable the production of commercially viable packaging with aesthetically suitable graphics, security features, and the like.

The packaging of a product in a package formed from metallized water-marked films described herein can be achieved using any suitable packaging method, e.g., FFS. In certain embodiments, the method for packaging a product may include providing a metallized water-marked film, folding the metallized water-marked film into a tubular form, forming a longitudinal sealed seam by joining opposite longitudinal edges of the tubularly formed metallized water-marked film, forming a first traverse end sealed seam, introducing a product into the tubularly formed metallized water-marked film, and forming a second traverse end sealed seam to enclose the product therein.

In embodiments, providing a metallized water-marked film may include forming the metallized water-marked film in off-line or in-line processes with respect to packaging of the product, and also may be formed in both horizontal and vertical FFS operations, among others. For example, the metallized water-marked film may be formed in-line just before the film is formed into a package body, filled with product, and sealed. Alternatively, the metallized water-marked film may be formed, then wound on a reel, e.g., by a packaging converter, and then loaded into the packaging equipment on which it is then unwound and formed into a package body, filled with product, and sealed.

### EXAMPLES

### Example 1

### Barrier Performance of Metallized Water-Marked Films

Three colored ink systems (white, yellow, and black) along with a clear ink system (i.e., 0.0% pigmentation) were reversed printed on a roll of base substrate (40,000 L/F of an 80″ wide 70 GA orientated polypropylene base film roll) at five different screen (100%, 75%, 50%, 25%, and 5%) by way of a flexographic printing process using 800 line anilox with 2.5 CV. The printed film was then metallized with aluminum using phase vapor deposition (PVD).

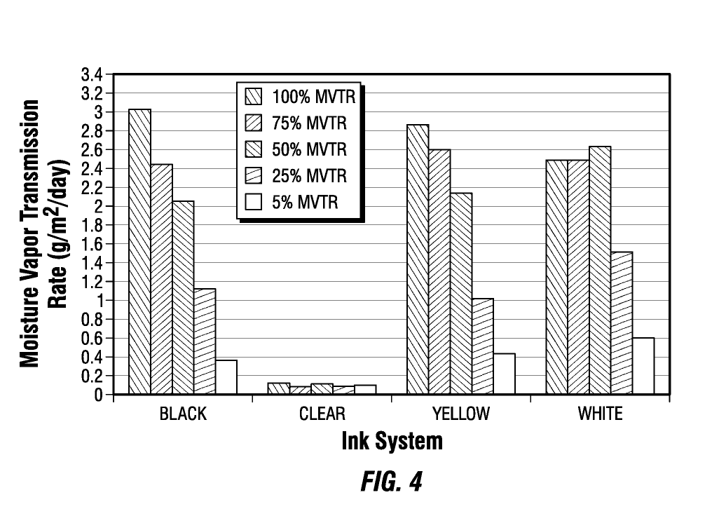

Two samples of each ink system (black, clear, yellow, and white) at each screen percentage (100%, 75%, 50%, 25% and 5%) were measured for (1) moisture vapor transmission rate using ASTM E96E. The results for moisture vapor transmission rate are shown in Table 1 below. The average moisture vapor transmission rate measured for each ink system at each screen percentage is graphically represented in FIG. 4.

TABLE 1
Moisture Vapor Transmission Rate (MVTR, g/m²/day)

| | Black | Clear | Yellow | White |
|---|---|---|---|---|
| 100% | 2.94 | 0.13 | 2.81 | 2.39 |
| | 3.12 | 0.11 | 2.91 | 2.56 |
| 75% | 2.42 | 0.09 | 2.45 | 2.18 |
| | 2.46 | 0.09 | 2.75 | 2.77 |
| 50% | 1.94 | 0.12 | 2.12 | 2.34 |
| | 2.16 | 0.11 | 2.15 | 2.92 |
| 25% | 1.09 | 0.08 | 0.94 | 1.54 |
| | 1.16 | 0.09 | 1.09 | 1.48 |
| 5% | 0.38 | 0.09 | 0.393 | 0.49 |
| | 0.36 | 0.11 | 0.47 | 0.69 |

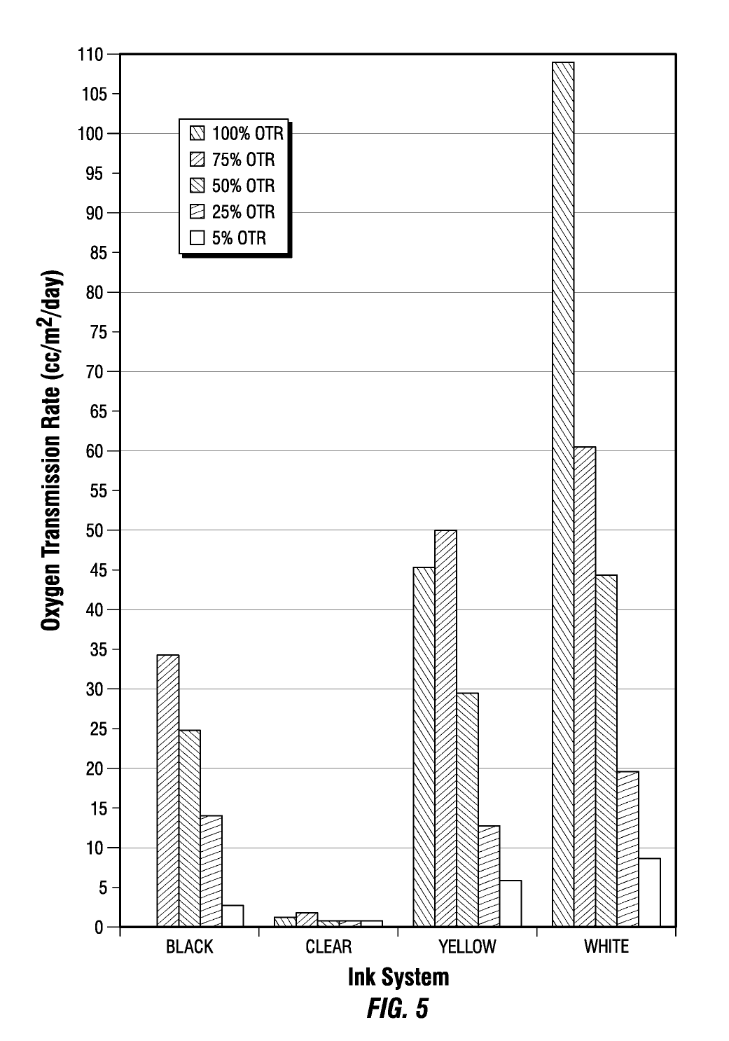

Two samples of each ink system (black, clear, yellow, and white) at each screen percentage (100%, 75%, 50%, 25% and 5%) were measured for oxygen transmission rate using ASTM D3985. The results for oxygen transmission rate are shown in Table 2 below. The average oxygen transmission rate measured for each ink system at each screen percentage is graphically represented in FIG. 5.

TABLE 2
Oxygen Transmission Rate (OTR, cc/m²/day)

| | Black | Clear | Yellow | White |
|---|---|---|---|---|
| 100% | FAIL | 1.56 | 44.01 | 108.66 |
| | FAIL | 1.28 | 46.28 | FAIL |
| 75% | 29.6 | 1.73 | 46.53 | 61.38 |
| | 39.3 | FAIL | 53.12 | 59.03 |
| 50% | 19.69 | 0.89 | 28.02 | 40.69 |
| | 29.61 | 0.83 | 30.9 | 47.67 |
| 25% | 17.853 | 0.91 | 11.46 | 16.09 |
| | 10.128 | 0.78 | 13.83 | 23.03 |
| 5% | 3.32 | 0.92 | 5.18 | 8.23 |
| | 1.72 | 0.59 | 6.83 | 8.99 |

As illustrated in Tables 1 and 2 and FIGS. 4 and 5, the metallized water-marked films as described herein (i.e., films with watermarks that are substantially free of pigment) had the lowest MVTRs and OTRs, thereby demonstrating minimal impact on the barrier properties of the metallized films compared to conventional metallized water-marked films (i.e., films with high pigmented watermarks).

For the purposes of describing and defining the present teachings, it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

It will be appreciated that various above-disclosed and other features and functions, or alternatives thereof, may be desirably combined into many other different products or applications. Various presently unforeseen or unanticipated alternatives, modifications, variations, or improvements therein may be subsequently made by those skilled in the art which are also intended to be encompassed by the following claims.

We claim:

1. A metallized water-marked film comprising:
a base substrate having a first surface and a second surface opposite the first surface;
a coating layer on at least a first portion of the first surface of the base substrate, wherein the coating layer is in the form of one or more markings that are each substantially free of pigment and the first surface of the base portion further includes a second portion uncoated with the coating layer; and
a metallized layer disposed over the coating layer and at least a portion of the second portion, wherein the coating layer is located between the base substrate and the metallized layer.

2. The metallized water-marked film of claim 1, wherein the coating layer comprises an ink system that comprises a nitro-cellulose-based ink system, a polyurethane-based ink system, a polyester-based ink system, a polyamide-based ink system, or combinations thereof.

3. The metallized water-marked film of claim 1, wherein the metallized layer comprises aluminum.

4. The metallized water-marked film of claim 1, further comprising an overcoat layer over at least the first portion and located between the metallized layer and at least the coating layer.

5. The metallized water-marked film of claim 4, wherein the overcoat layer comprises acrylics, acrylates, styrene, polyolefins, polyamides, polyesters, polyurethanes, polyvinyl alcohols, or combinations thereof.

6. The metallized water-marked film of claim 1, wherein each of the one or more markings are in the form of one or more words, one or more numbers, one or more letters, one or more shapes, one or more symbols, one or more patterns, or combinations thereof.

7. A method for fabricating a metallized water-marked film, comprising:
applying a coating layer on at least a first portion of a first surface of a base substrate, wherein the coating layer is in the form of one or more markings that are each substantially free of pigment and the first surface of the base portion further includes a second portion uncoated with the coating layer; and
disposing a metallized layer over the coating layer and at least a portion of the second portion, wherein the coating layer is located between the base substrate and the metallized layer.

8. The method of claim 7, wherein the step of applying the coating layer comprises flexographic printing, gravure printing, or a combination of flexographic printing and gravure printing the coating layer on at least the first portion of the first surface of the base substrate.

9. The method of claim 7, wherein the step of disposing the metallized layer comprises vacuum depositing, the metallized layer over the coating layer and at least a portion of the second portion.

10. The method of claim 7, further comprising applying an overcoat layer over at least the first portion, wherein the metallized layer is disposed on a first surface of the overcoat layer and at least a portion of the second portion of the base substrate such that the overcoat layer is located between the metallized layer and at least the coating layer.

11. A package for containing a product therein, said package comprising:
a flexible container formed from the metallized water-marked film of claim 1, wherein the flexible container has a front side and a back side sealed together along at least one longitudinal seam and two lateral end seams.

12. The package of claim 11, wherein the coating layer comprises an ink system that comprises a nitro-cellulose-based ink system, a polyurethane-based ink system, a polyester-based ink system, a polyamide-based ink system, or combinations thereof.

13. The package of claim 11, wherein the metallized layer comprises aluminum.

14. The package of claim 11, wherein the metallized water-marked film further comprises an overcoat layer over at least the first portion and located between the metallized layer and at least the coating layer.

15. The package of claim 14, wherein the overcoat layer comprises acrylics, acrylates, styrene, polyolefins, polyamides, polyesters, polyurethanes, polyvinyl alcohols, or combinations thereof.

16. The package of claim 11, wherein each of the one or more markings are in the form of one or more words, one or more numbers, one or more letters, one or more shapes, one or more symbols, one or more patterns, or combinations thereof.

17. A method for fabricating a package for containing a product therein, said method comprising:
forming the metallized water-marked film of claim 1 into a flexible container having a front side and a back side sealed together along at least one longitudinal seam and two lateral end seams.

18. A method for packaging a product, said method comprising:
providing a metallized water-marked film of claim 1;
folding the metallized water-marked film into a tubular form;
forming a longitudinal sealed seam by joining opposite longitudinal edges of the tubularly formed metallized water-marked film;
forming a first traverse end sealed seam;
introducing a product into the tubularly formed metallized water-marked film; and
forming a second traverse end sealed seam to enclose the product therein.

19. A roll of flexible film for forming a package for containing a product therein, said roll of flexible film comprising the metallized water-marked film of claim 1.
